(19) United States
(12) Patent Application Publication
(10) Pub. No.: US 2011/0108118 A1
(43) Pub. Date: May 12, 2011

(54) THIN-FILM SOLAR CELL AND METHOD OF MANUFACTURING THE SAME

(75) Inventors: Hiroya Yamarin, Tokyo (JP); Hidetada Tokioka, Tokyo (JP); Mikio Yamamuka, Tokyo (JP)

(73) Assignee: MITSUBISHI ELECTRIC CORPORATION, Tokyo (JP)

(21) Appl. No.: 13/002,403

(22) PCT Filed: May 22, 2009
(86) PCT No.: PCT/JP2009/059445

§ 371 Date: Jan. 3, 2011

(30) Foreign Application Priority Data
Jul. 7, 2008 (JP) 2008-177198

(51) Int. Cl. H01L 31/0264; H01L 31/18

(52) U.S. Cl. 136/265; 136/252; 438/72; 257/E31.126

(57) ABSTRACT

A thin-film solar cell in which a transparent electrode having fine surface irregularities with small surface roughness and substantially uniform in-plane resistance is realized can be obtained by forming a plurality of first transparent conductive films separated from one another in a substrate surface on a transparent insulative substrate, forming a second transparent conductive film on the first transparent conductive films, etching the second transparent conductive film in a granular shape and forming first granular members dispersed on the first transparent conductive films, forming a power generation layer on the first transparent conductive films and on the dispersed first granular members, forming a rear-side electrode layer on the power generation layer.

### TECHNICAL FIELD

The present invention relates to a thin-film solar cell and a method of manufacturing the same, and, more particularly to a thin-film solar cell employing a light trapping technology and a method of manufacturing the same.

### BACKGROUND ART

At present, as a light trapping technology used for a thin-film solar cell, in the case of a thin-film solar cell on which light is made incident from a transparent insulative substrate side, a method of forming an irregular structure on the surface of a transparent conductive film formed on the transparent insulative substrate is used. In the light trapping technology for forming the irregular structure, it is generally known that light conversion efficiency of the thin-film solar cell is improved by a reduction in light reflectance and a light diffusion effect. Specifically, the light made incident from the transparent insulative substrate side is made incident on a photoelectric conversion layer after being scattered on an interface between the transparent conductive film having an irregular shape and the photoelectric conversion layer. Therefore, the light is made incident generally obliquely on the photoelectric conversion layer. Because the light is made incident obliquely on the photoelectric conversion layer, a substantial optical path of the light is extended and absorption of the light increases. Therefore, a photoelectric conversion characteristic of a photovoltaic element is improved and output current increases.

In the past, a tin oxide (SnO₂) transparent conductive film is well-known as the transparent conductive film having the irregular structure. In general, the irregular structure formed on the SnO₂ transparent conductive film is formed by growing crystal grains having a diameter of several tens nanometers to several hundreds nanometers on a film surface with a thermal chemical vapor deposition (CVD) method. However, to form a satisfactory irregular structure on the surface of the SnO₂ film, because high-temperature process at 500° C. to 600° C. is necessary and film thickness of about 1 micrometer is required, this is a cause of an increase in manufacturing cost.

Therefore, in recent years, zinc oxide (ZnO) is spreading as a material replacing SnO₂ from the viewpoint of excellent plasma resistance and abundance of resources. However, in the case of ZnO, to form a satisfactory irregular structure on the surface, film thickness of about 2 micrometers is required. Therefore, as a method of forming an irregular structure having a satisfactory light trapping effect even when a ZnO film is formed as a thin film by low-temperature formation, a technology for forming a transparent conductive film on a glass substrate with a sputtering method and etching the transparent conductive film with acid to form an irregular structure on the surface thereof is reported. According to this method, a cost reduction of a solar cell device is expected. Patent Document 1 described below discloses a method of immersing the surface of a zinc oxide film laminated on a high-reflection metal film in a solution containing bivalent carboxylic acid and forming an irregular structure with a substance separated out by a chemical reaction.

For example, Patent Document 2 discloses a method of placing powdered glass on flat glass and fusing the glasses to form an irregular structure. Patent Documents 3 and 4 disclose that an irregular structure is formed on the surface of a transparent insulative substrate by sandblasting.
Patent Document 1: Japanese Patent Application Laid-open No. H06-196734
Patent Document 2: Japanese Patent Application Laid-open No. S62-98677
Patent Document 3: Japanese Patent Application Laid-open No. H09-199745
Patent Document 4: Japanese Patent Application Laid-open No. H07-122764
Non-Patent Document: Yoshiyuki Nasuno et al., “Effects of Substrate Surface Morphology on Microcrystalline Silicon Solar Cells”, Jpn. J. Appl. Phys., The Japan Society of Applied Physics, 1 Apr. 2001, vol 40, pp. L303-L305.

### DISCLOSURE OF INVENTION

### Problem to be Solved by the Invention

However, in the technology for forming an irregular structure on the surface of a film by etching the surface with acid, because pinholes due to steep projections are locally formed because of etching fluctuation and short-circuit or the like is caused by the pinholes, yield and reliability of a thin-film solar cell are deteriorated. In Patent Document 1, an aspect ratio of the formed irregular structure increases, leak is induced in an element because steep slopes are formed on irregularities, and reliability and yield are deteriorated. In the method of depositing particles and the mechanical machining method as in Patent Document 2 and Patent Documents 3 and 4, irregularities having a large step compared with the thickness of a photoelectric conversion layer such as an amorphous film tend to be formed and surface roughness such as Rmax increases. Therefore, a large residual occurs in the photoelectric conversion layer to cause disconnection or the like and performance of the thin-film solar cell is deteriorated.

A technology for using transparent electrodes formed in a texture shape as electrodes on a substrate side has a limit in improvement of conversion efficiency (see, for example, Non-Patent Document 1). This is because the transparent electrodes formed in the texture shape induce structural defects in a semiconductor thin film formed thereon. If irregularities of the transparent electrodes are increased, light absorption of a semiconductor layer can be increased. However, the increase in the irregularities of the transparent electrodes increases the structural defects induced in the semiconductor thin film and reduces output voltage. Therefore, there is a limit in improvement of conversion efficiency by the formation of the irregular structure in the transparent electrodes. Because of such a background, there is a demand for a new technology for improving the conversion efficiency.

The present invention has been devised in view of the above and it is an object of the present invention to obtain a thin-film solar cell in which deterioration in reliability and a photoelectric conversion characteristic due to a texture structure for light scattering is prevented and that has a satisfactory light trapping effect and is excellent in the reliability and the photoelectric conversion characteristic and a method of manufacturing the thin-film solar cell.

### Means for Solving Problem

In order to solve the aforementioned problems and attain the aforementioned object, a method of manufacturing a thin-film solar cell according to one aspect of the present invention is constructed in such a manner as to include: a first transparent conductive film forming step for forming a plurality of first transparent conductive films separated from one another in a substrate surface on a transparent insulative substrate; a second transparent conductive film forming step for forming a second transparent conductive film on the first transparent conductive films; an etching step for etching the second transparent conductive film in a granular shape and forming first granular members dispersed on the first transparent conductive films; a power generation layer forming step for forming a power generation layer on the first transparent conductive films and on the dispersed first granular members; and a rear-side electrode layer forming step for forming a rear-side electrode layer on the power generation layer.

### Effect of the Invention

According to the present invention, transparent electrodes having fine surface irregularities with small surface roughness and having substantially uniform in-plane resistances can be realized. Consequently, there is an effect that it is possible to obtain a thin-film solar cell in which there are few defects of a power generation layer due to a texture structure for light scattering and short-circuit and leak are prevented and that has a satisfactory light trapping effect and is excellent in reliability and a photoelectric conversion characteristic.

### BRIEF DESCRIPTION OF DRAWINGS

FIG. 1 is a sectional view of a schematic configuration of a thin-film solar cell according to a first embodiment of the present invention.

FIG. 2-1 is a sectional view for explaining a manufacturing process for the thin-film solar cell according to the first embodiment of the present invention.

FIG. 2-2 is a sectional view for explaining the manufacturing process for the thin-film solar cell according to the first embodiment of the present invention.

FIG. 2-3 is a sectional view for explaining the manufacturing process for the thin-film solar cell according to the first embodiment of the present invention.

FIG. 2-4 is a sectional view for explaining the manufacturing process for the thin-film solar cell according to the first embodiment of the present invention.

FIG. 2-5 is a sectional view for explaining the manufacturing process for the thin-film solar cell according to the first embodiment of the present invention.

FIG. 2-6 is a sectional view for explaining the manufacturing process for the thin-film solar cell according to the first embodiment of the present invention.

FIG. 2-7 is a sectional view for explaining the manufacturing process for the thin-film solar cell according to the first embodiment of the present invention.

FIG. 3 is a sectional view of a schematic configuration of another thin-film solar cell according to the first embodiment of the present invention.

FIG. 4 is a characteristic chart of haze ratios after transparent conductive film formation in thin-film solar cells of an example 1 and conventional examples 1 and 2.

FIG. 5 is a sectional view of a schematic configuration of a thin-film solar cell of a tandem type according to a second embodiment of the present invention.

FIG. 6-1 is a sectional view for explaining a manufacturing process for the thin-film solar cell according to the second embodiment of the present invention.

FIG. 6-2 is a sectional view for explaining the manufacturing process for the thin-film solar cell according to the second embodiment of the present invention.

FIG. 6-3 is a sectional view for explaining the manufacturing process for the thin-film solar cell according to the second embodiment of the present invention.

FIG. 6-4 is a sectional view for explaining the manufacturing process for the thin-film solar cell according to the second embodiment of the present invention.

FIG. 7 is a sectional view of a schematic configuration of another thin-film solar cell according the second embodiment of the present invention.

FIG. 8-1 is a sectional view of a schematic configuration of a thin-film solar cell of a tandem type according to a third embodiment of the present invention.

FIG. 8-2 is a sectional view for explaining a manufacturing process for the thin-film solar cell according to the third embodiment of the present invention.

FIG. 8-3 is a sectional view for explaining the manufacturing process for the thin-film solar cell according to the third embodiment of the present invention.

### EXPLANATIONS OF LETTERS OR NUMERALS

1 Transparent insulative substrate (glass substrate)
2 First transparent conductive film(s)
3 Second transparent conductive film
4a Zinc oxide crystal grains
4b Conductive oxide light scatterers
4c Conductive oxide light scatterers
5 First power generation layer
6 Rear-side electrode layer
7 Texture-like transparent conductive film
8 Second power generation layer
9 Intermediate layer
10 Thin-film solar cell
11 Thin-film solar cell
20 Thin-film solar cell
30 Thin-film solar cell

### BEST MODE(S) FOR CARRYING OUT THE INVENTION

Embodiments of a thin-film solar cell and a method of manufacturing the same according to the present invention are explained in detail below with reference to the drawings. The present invention is not limited to the following description and can be changed as appropriate without departing the spirit of the present invention. In the drawings referred to below, for ease of understanding, in some case, scales of members are different from actual scales. The same holds true among the drawings.

### First Embodiment

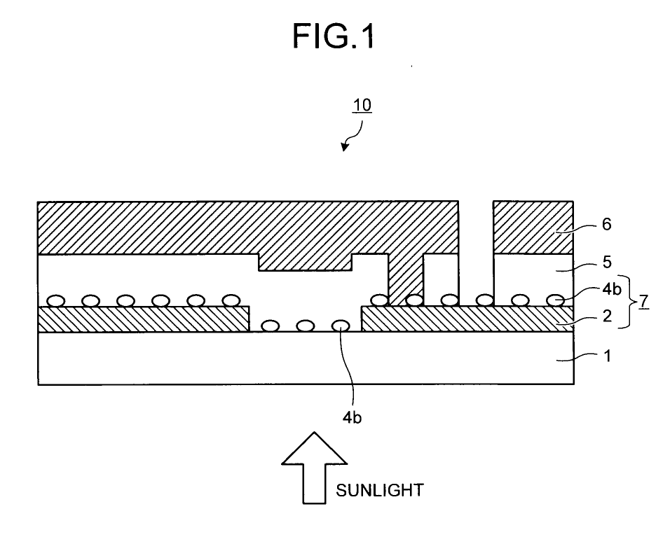

FIG. 1 is a sectional view showing a schematic configuration of a thin-film solar cell 10 according to a first embodiment of the present invention. The thin-film solar cell 10 includes a transparent insulative substrate 1, a first transparent conductive film (transparent electrode layer) 2 formed on the transparent insulative substrate 1 and serving as a first electrode layer, a conductive oxide light scatterers 4b formed on the transparent insulative substrate 1 and the first transparent conductive film 2, a first power generation layer 5 formed on the conductive oxide light scatterers 4b, and a rear-side electrode layer 6 formed on the first power generation layer 5 and serving as a second electrode layer.

The first power generation layer 5 includes at least two or more layers. In this embodiment, the first power generation layer 5 includes, from the first transparent conductive film 2 side, a P-type amorphous silicon film, an i-type amorphous silicon film, and an N-type amorphous silicon film (not shown).

In the thin-film solar cell 10 according to the first embodiment configured as explained above, the conductive oxide light scatterers 4b, which are fine granular conductive light scatterers, are formed on the first transparent conductive film 2. The conductive oxide light scatterers 4b and the first transparent conductive film 2 are formed as a texture-like transparent conductive film 7 having small surface roughness as a whole. Light made incident from the transparent insulative substrate 1 side is made incident on the first power generation layer 5 after being scattered on an interface between the first transparent conductive film 2 having the conductive oxide light scatterers 4b and the first power generation layer 5. Therefore, the light is made incident generally obliquely on the first power generation layer 5. Because the light is made incident obliquely on the first power generation layer 5, a substantial optical path of the light is extended and absorption of the light increases. Therefore, a photoelectric conversion characteristic of the thin-film solar cell is improved and output current increases. Consequently, a thin-film solar cell that has a satisfactory light diffusion effect and is excellent in conversion efficiency is realized.

On the conductive oxide light scatterers 4b, irregularities having a difference of elevation equal to or smaller than 1 micrometer are equally formed such that there is no steep slope on irregularities of the transparent conductive film. Consequently, structural defects induced by an irregular structure for light scattering in the first power generation layer 5 formed on the first transparent conductive film 2 are reduced. Short-circuit and leak due to the structural defects induced in the first power generation layer 5 are reduced.

Therefore, in the thin-film solar cell 10 according to the first embodiment, a thin-film solar cell is realized that has a satisfactory light diffusion effect, in which short-circuit and leak of the first power generation layer 5 are reduced, and that is excellent in reliability and yield.

FIGS. 2-1 to 2-7 are sectional views for explaining a manufacturing process for the thin-film solar cell 10 according to the first embodiment. A method of manufacturing the thin-film solar cell 10 is explained below with reference to FIGS. 2-1 to 2-7. First, the transparent insulative substrate 1 is prepared. As the transparent insulative substrate 1, for example, a glass substrate is used (hereinafter referred to as glass substrate 1). In the explanation in this embodiment, a no alkali glass substrate is used. An inexpensive soda lime glass substrate can be used as the glass substrate 1. However, in this case, it is advisable to form an SiO₂ film at thickness of about 100 nanometers by a plasma chemical vapor deposition (PCVD) method to prevent diffusion of an alkali component from the substrate.

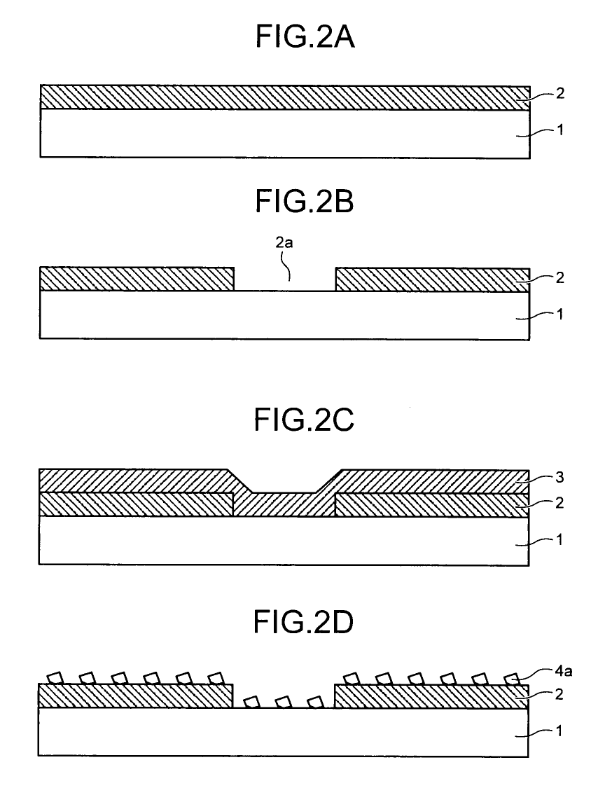

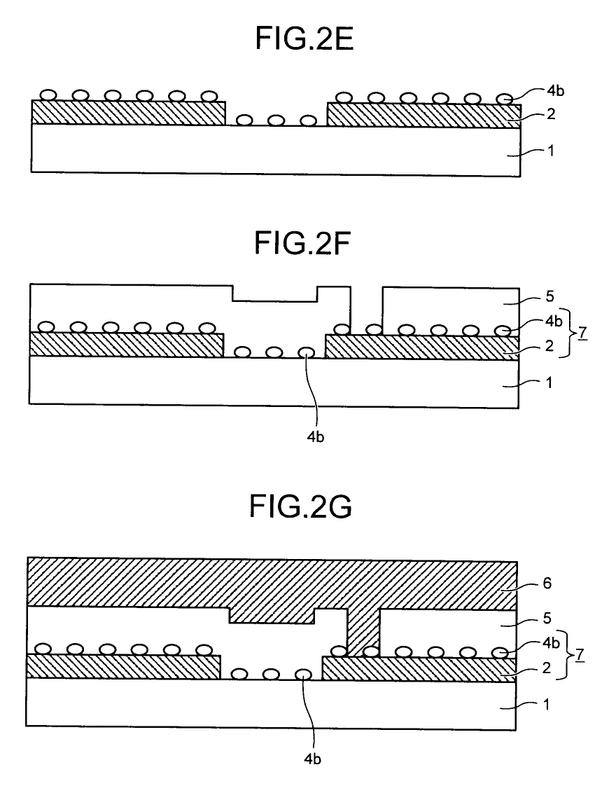

Subsequently, the first transparent conductive film 2 is formed on one surface side of the glass substrate (FIG. 2-1). As the first transparent conductive film 2, for example, an indium tin oxide (ITO) film having thickness of 0.4 micrometer and containing 10 wt % or less of an SnO₂ dopant is deposited and formed by the sputtering method. In this embodiment, an SnO₂-doped ITO film is used as the first transparent conductive film 2. However, the first transparent conductive film 2 is not limited to this. The first transparent conductive film 2 can be an a-ITO film in an amorphous state, an SnO₂ film, or the first transparent conductive film 2 formed by laminating these films. The first transparent conductive film 2 only has to be the first transparent conductive film 2 having higher acid resistance than that of ZnO and having high light transmission properties and low specific resistance properties. As the first transparent conductive film 2, a transparent electrode having an irregular shape obtained by forming tin oxide on the glass substrate 1 with the thermal CVD method can be used.

Thereafter, patterning of the first transparent conductive film 2 is performed (FIG. 2-2). The first transparent conductive film 2 is separated into strip-like shapes to form a first open groove (a scribe line) 2a. The width of the strip is desirably within 1 centimeter when a resistance loss due to surface resistance of the first transparent conductive film 2 is taken into account. Usually, to pattern the first transparent conductive film 2 into such a strip shape, laser scribe is used. To obtain a plurality of the first transparent conductive films 2 separated from each other in a substrate surface on the transparent insulative substrate 1 in this way, a method of etching the first transparent conductive film 2 using a resist mask formed by photoengraving or the like or a method such as an evaporation method using a metal mask is also possible.

Subsequently, a second transparent conductive film 3 is formed on the first transparent conductive films 2 including the first open groove (the scribe line) 2a. As the second transparent conductive film 3, for example, a ZnO film having thickness equal to or larger than 0.1 micrometer is deposited and formed by the sputtering method. In this embodiment, a ZnO film having thickness of 500 nanometers doped with 3 wt % of aluminum oxide (Al₂O₃) is used as the second transparent conductive film 3. However, the second transparent conductive film 3 is not limited to this. The second transparent conductive film 3 can be a ZnO film containing, as a dopant, at least one or more elements selected out of aluminum (Al), gallium (Ga), indium (In), boron (B), yttrium (Y), silicon (Si), zirconium (Zr), and titanium (Ti) or a transparent conductive film formed by laminating these elements. The second transparent conductive film 3 only has to be a transparent conductive film having light transmission properties. As a method of forming the first transparent conductive films 2 and the second transparent conductive film 3, a physical method such as a vacuum evaporation method or an ion plating method or a chemical method such as a spray method, a dip method, or a CVD method can be used.

Subsequently, first etching is performed to etch the second transparent conductive film 3 and form zinc oxide crystal grains 4a (FIG. 2-4). In the first etching, after the glass substrate 1 on which the second transparent conductive film 3 is formed is immersed for ninety seconds in an oxalic acid solution having liquid temperature of 30° C. containing 5 wt % or less of oxalic acid as first acid, pure water cleaning is performed for one minute or more, and the glass substrate 1 is dried, whereby the zinc oxide crystal grains 4a are formed on the first transparent conductive films 2 and the glass substrate 1 in the first open groove (the scribe line) 2a. Such processing is realized by microscopically etching a film non-uniformly in a film surface by etching liquid. For example, if the second transparent conductive film 3 after formation is a film including microcrystal, liquid for preferentially etching grain boundaries of the microcrystal can be used. From SEM observation after the drying, formation of the zinc oxide crystal grains 4a of about 1000 nanometers to 5000 nanometers is recognized. In this first etching process, it is desirable that an etching condition is adjusted to expose a part of the surface of the glass substrate 1 in the first open groove 2a. In particular, it is desirable that the zinc oxide crystal grains 4a are formed as grains that do not come into contact with one another. Consequently, the second transparent conductive film 3 is not present as a continuous film between the separated first transparent conductive films 2. The separated first transparent conductive films 2 are insulated from each other. Short-circuit between power generation elements formed thereon can be prevented. The zinc oxide crystal grains 4a formed to be insulated from one another in the first open groove (the scribe line) 2a have an effect of light scattering to the first power generation layer 5. Therefore, the zinc oxide crystal grains 4a contribute to improvement of short-circuit current.

Subsequently, second etching is performed to etch the zinc oxide crystal grains 4a and form conductive oxide light scatterers 4b including zinc oxide crystal grains on the glass substrate 1 and the first transparent conductive films 2 (FIG. 2-5). In the second etching, after the glass substrate 1 on which the zinc oxide crystal grains 4a are formed is immersed for thirty seconds in, for example, a hydrochloric acid solution having liquid temperature of 30° C. containing 1 wt % or less of hydrochloric acid as second acid, pure water cleaning is performed for one minute or more, and the glass substrate 1 is dried, whereby zinc oxide crystal grains as the substantially-spherical-shaped conductive oxide light scatterers 4b having a smooth surface are formed on the first transparent conductive films 2 and the glass substrate 1 in the first open groove (the scribe line) 2a. From SEM observation after the drying, formation of substantially-spherical-shaped zinc oxide crystal grains of about 500 nanometers to 600 nanometers is recognized. In this way, the second etching process is an etching process for reducing particles of the zinc oxide crystal grains 4a formed in the first etching process and smoothing the shape of the particles. By adjusting an etching condition, it is possible to set the resistance in a surface direction of the conductive oxide light scatterers 4b sufficiently high and suppress occurrence of short-circuit among elements and leak current.

As an acid solution used for the second etching, an acid solution having etching speed of ZnO ten or more times and preferably twenty or more times as high as etching speed of SnO₂ and ITO is used. For the second etching, it is advisable to use etching liquid having a large etching speed ratio of the second transparent conductive film 3 to etching speed of the first transparent conductive films 2. Consequently, when the glass substrate 1 is immersed in the acid solution for the second time, only the ZnO particles are etched without substantially changing SnO₂ and ITO of a base. The acid solutions are desirably acid solutions for etching the surface of ZnO into smooth surface compared with oxalic acid.

As a result of continuously immersing the glass substrate 1 in the two kinds of acid solutions having different characteristics in this way, SnO₂ and ITO of the base remain as a film having sufficient conductivity, the fine ZnO particles (the zinc acid crystal grains) having the smooth surface on SnO₂ and ITO remain as the conductive oxide light scatterers 4b, and SnO₂ and ITO and the ZnO particles are formed as the texture-like transparent conductive film 7 as a whole. In the second etching, a compound of oxalic acid as first acid formed on the surface of the zinc oxide crystal grains 4a can be removed. This makes it possible to suppress a resistance loss via the conductive oxide light scatterers 4b formed between the first transparent conductive films 2 and the first power generation layer 5.

By performing the etching explained above, it is possible to easily control the height of the irregularities as the transparent conductive film, i.e., the height of the conductive oxide light scatterers 4b (the zinc acid crystal grains) to 1 micrometer or less and easily control the height to about 100 nanometers to 1000 nanometers as large as about the wavelength of light in the visible light domain. Further, it is possible to easily control the height to about 600 nanometers as large as about a half of the wavelength of light in the visible light domain. Consequently, compared with large irregularities (steep irregularities) formed on the surface of the transparent conductive film in the related art, it is possible substantially uniformly form irregularities having size as large about a middle between small irregularities and large irregularities in the related art and eliminate steep slopes in the irregularities.

As the acid solution used in the second etching, 1 wt % of hydrochloric acid solution is used in this embodiment. However, an acid solution used in the second etching is not limited to this. Examples of the acid solution include a solution containing one kind or two or more kinds selected out of a group including hydrochloric acid, sulfuric acid, nitric acid, fluoric acid, acetic acid, and formic acid. Among the acids, hydrochloric acid and acetic acid are desirable. When the separation resistance of the formed first transparent conductive film 2 was measured, the separation resistance was equal to or larger than 10 megaohms. The separation resistance between the adjacent first transparent conductive films 2 is desirably in a range of separation resistance equal to or larger than 1 megaohm to separation resistance equal to or smaller than 100 megaohms. Unless there is sufficient separation resistance between the transparent electrodes (the first transparent conductive films 2), as conversion efficiency of an integrated thin-film solar cell, a fill factor falls because of leak current between patterns. When the separation resistance is several hundreds kiloohms, the influence of a leak current component between the adjacent transparent electrodes (first transparent conductive films 2) increases, leading to a substantial fall in the fill factor. It is ideal that adjacent patterns are completely separated. However, when a thin-film solar cell is formed on the patterned transparent electrodes (the first transparent conductive films 2) having separation resistance equal to or larger than 1 megaohm, it is possible to obtain a solar cell having satisfactory characteristics. In a solar cell formed by using the manufacturing method of the present invention, a value equivalent to separation resistance (1 megaohm to 10 megaohms) in the patterning of SnO₂ in the past is obtained. It goes without saying that a thin-film solar cell having a high fill factor can be formed and contributes to improvement of conversion efficiency.

Subsequently, the first power generation layer 5 is formed on the first transparent conductive films 2 and the conductive oxide light scatterers 4b (the zinc oxide crystal grains) by the PCVD method. In this embodiment, as the first power generation layer 5, a P-type amorphous silicon carbonate film (a-SiC film), a buffer layer, an i-type amorphous silicon film (a-Si film), and an N-type amorphous silicon film (a-Si film) are formed in order from the first transparent conductive films 2 side. Patterning is applied to the first power generation layer 5 laminated and formed in this way by the laser scribe in the same manner as the patterning for the first transparent conductive films 2 (FIG. 2-6).

Subsequently, the rear-side electrode layer 6 serving as the second electrode layer is formed on the first power generation layer 5 (FIG. 2-7). As the rear-side electrode layer 6, for example, an aluminum (Al) film having thickness of 200 nanometers is deposited and formed by the sputtering method. In this embodiment, the aluminum (Al) film having thickness of 200 nanometers is formed as the rear-side electrode layer 6. However, the rear-side electrode layer 6 is not limited to this. Silver (Ag) having high reflectance can be used as a metal electrode. A transparent conductive film of ZnO, ITO, SnO₂, or the like can be formed to prevent metal diffusion to silicon.

After the formation of the rear-side electrode layer 6, a metal layer is locally blown off by a laser together with a semiconductor layer (the first power generation layer 5), whereby the semiconductor layer and the metal layer are separated to correspond to a plurality of unit elements (power generation areas). Because it is difficult to cause the rear-side electrode layer 6 having the high reflectance to directly absorb the laser, the semiconductor layer (the first power generation layer 5) is caused to absorb laser beam energy and the metal layer is locally blown off together with the semiconductor layer (the first power generation layer 5), whereby the semiconductor layer and the metal layer are separated to correspond to the unit elements (the power generation areas). According to the process explained above, the thin-film solar cell 10 shown in FIG. 1 is formed.

In the method of manufacturing a thin-film solar cell according to the first embodiment explained above, the conductive oxide light scatterers 4b as fine granular conductive light scatterers are formed on the first transparent conductive films 2 and the texture-like transparent conductive film 7 having small surface roughness as a whole is formed. The second transparent conductive film 3 is etched by the two kinds of acid solutions having different characteristics, whereby it is possible to form the conductive oxide light scatterers 4b to equalize irregularities having a difference of elevation equal to or smaller than 1 micrometer such that there is no steep slope on irregularities of the transparent conductive film as a whole. In this way, the conductive oxide light scatterers 4b are fine particles dispersed on the first transparent conductive films 2 including generally smooth continuous films. The height of the particles is smaller than the thickness of the second transparent conductive film 3. Therefore, it is possible to accurately realize a structure having a fine irregular surface with a small surface roughness Rmax. This makes it possible to reduce structural defects induced by the irregular structure for light scattering in the first power generation layer 5 formed on the first transparent conductive films 2 and manufacture a thin-film solar cell in which short-circuit and leak due to the structure defects induced in the first power generation layer 5 are reduced and that is excellent in reliability and yield. Because the first transparent conductive film 2 including the continuous film is present under the conductive oxide light scatterers 4b, in-plane resistances of the transparent electrodes are substantially uniform. Further, it is possible to manufacture a thin-film solar cell having high conversion efficiency by using the sunlight having wavelength not contributing to power generation in the past.

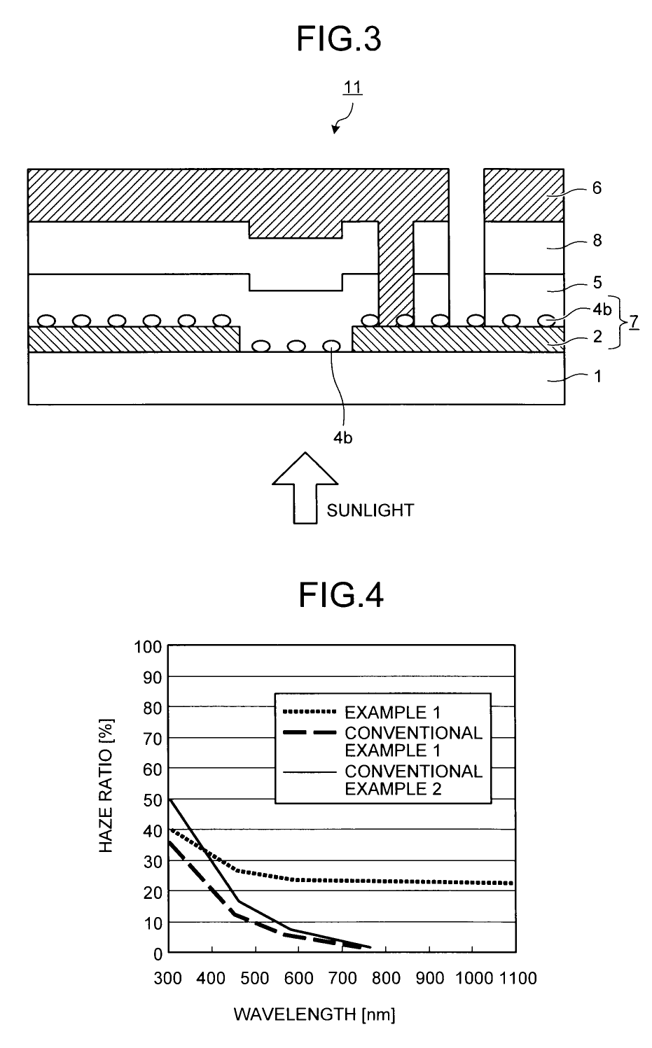

In the above explanation, amorphous silicon is used for the first power generation layer 5. However, it is also possible to form a thin-film solar cell 11 of a tandem type having the first power generation layer 5 and a second power generation layer 8 as shown in FIG. 3 using an amorphous silicon semiconductor of amorphous silicon germanium, amorphous silicon carbide, or the like and crystalline silicon thereof. A satisfactory characteristic is obtained by forming a pin structure of the layers. FIG. 3 is a sectional view of a schematic configuration of another thin-film solar cell according to the first embodiment.

The present invention is explained below based on specific examples. The thin-film solar cell 10 manufactured by the method of manufacturing a thin-film solar cell according to the first embodiment explained above is a thin-film solar cell of an example 1. As a conventional example, a zinc oxide film having an irregular structure formed by etching by acid on the surface thereof was formed on the glass substrate 1 as a transparent conductive film in the same manner as explained above and a thin-film solar cell was manufactured. This thin-film solar cell is the thin-film solar cell of a conventional example 1. As another conventional example, tin oxide was formed as transparent electrodes having an irregular shape on the glass substrate 1 same as that explained above by the thermal CVD method and a thin-film solar cell was manufactured. This thin-film solar cell is a thin-film solar cell of a conventional example 2.

Light having an AM (air mass) of −1.5 and 100 mW/cm² was made incident on the thin-film solar cells from a substrate side using a solar simulator, short-circuit currents (mA/cm²) were measured at 25° C., and characteristics of the thin-film solar cells were evaluated. A result of the evaluation is shown in Table 1.

TABLE 1

| | Short-circuit currents |
|---|---|
| | [mA/cm²] |
| Example 1 | 15.5 |
| Conventional example 1 | 13 |
| Conventional example 2 | 14.3 |

It is recognized from Table 1 that, whereas short-circuit currents of the thin-film solar cells of the conventional examples 2 and 3 are respectively 13 mA/cm² and 14.3 mA/cm², short-circuit current of the thin-film solar cell of the example 1 is 15.5 mA/cm² and the short-circuit current (mA/cm²) is improved about 8% or more in the thin-film solar cell of the example 1 compared with the solar cells of the conventional examples 2 and 3. This is because the conductive oxide light scatterers 4b are formed to equalize irregularities such that there is no steep slope on irregularities of the transparent conductive film as a whole. Further, this is also considered to be because, since the zinc oxide crystal grains 4a formed to be insulated from one another in the first open groove (the scribe line) 2a have the effect of light scattering to the first power generation layer 5, an effect of causing light not originally contributing to power generation to contribute to improvement of short-circuit current is added.

Specifically, the light made incident from the transparent insulative substrate side is made incident on the first power generation layer 5 after being scattered on the interface between the first transparent conductive films 2 having the conductive oxide light scatterers 4b and the first power generation layer 5. Therefore, the light is made incident generally obliquely on the first power generation layer 5. Because the light is made incident obliquely on the first power generation layer 5, a substantial optical path of the light is extended and absorption of the light increases. Therefore, a photoelectric conversion characteristic of the thin-film solar cell is improved and output current increases.

FIG. 4 is a characteristic chart of haze ratios (diffuse transmittance/total light transmittance)×100 after transparent conductive film formation in the thin-film solar cells of the example 1 and the conventional examples 1 and 2. The haze ratio is a numerical value representing a degree of diffusion of light. As it is seen from FIG. 4, in the transparent conductive film of the example 1, a fall in the haze ratio is small even if wavelength increases. A decrease in the light diffusion effect is small. On the other hand, in the transparent conductive film of the conventional examples 1 and 2, the haze ratio substantially decreases as wavelength increases. A decrease in the light diffusion effect is large. The scattering effect at large wavelength is large in the example 1. This is considered to be because, since the conductive oxide light scatterers 4b are formed by diffused grains, spaces among projected portions are large compared with those in the past.

In other words, it is seen that, in the transparent conductive film of the example 1, compared with the conventional examples 1 and 2, a sufficient light diffusion effect is obtained as the wavelength is larger. Therefore, in the thin-film solar cell of the example 1, it is possible to increase the light trapping effect compared with the texture structure in the past and improve conversion efficiency. In other words, in the thin-film solar cell of the example 1, it is possible to perform power generation using the sunlight not contributing to power generation in the conventional examples 1 and 2. It can be said that a thin-film solar cell with improved conversion efficiency is realized.

With the thin-film solar cell and the method of manufacturing the same according to the first embodiment explained above, a thin-film solar cell is realized that has a satisfactory light trapping effect by the texture structure for light scattering, in which deterioration in reliability and a photoelectric conversion characteristic due to the texture structure for light scattering is prevented, and that is excellent in the reliability and the photoelectric conversion characteristic and can be used for a long period.

### Second Embodiment

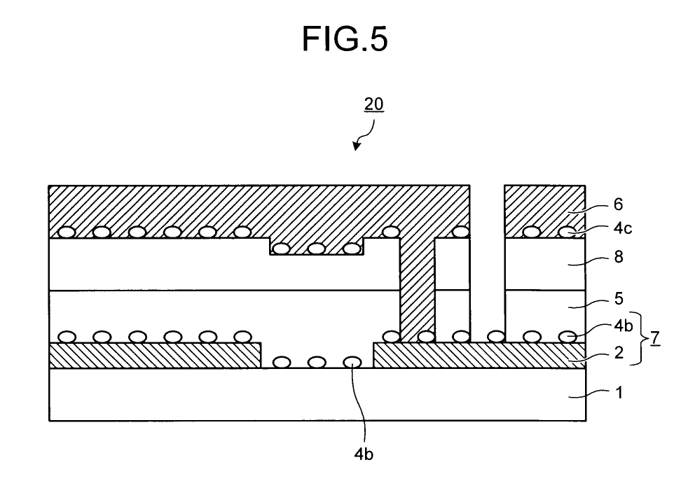

FIG. 5 is a sectional view of a schematic configuration of a thin-film solar cell 20 of a tandem type according to a second embodiment of the present invention. The thin-film solar cell 20 of the tandem type according to the second embodiment is a modification of the thin-film solar cell 11 according to the first embodiment. The thin-film solar cell 20 includes the transparent insulative substrate 1, the first transparent conductive films (the transparent electrode layers) 2, the conductive oxide light scatterers 4b, the first power generation layer 5, the second power generation layer 8, conductive oxide light scatterers 4c, and the rear-side electrode layer 6. In FIG. 5, members same as those of the thin-film solar cells 10 and 11 according to the first embodiment are denoted by reference numerals and signs same as those in FIGS. 1 and 3 and explanation of the members is omitted.

The thin-film solar cell 20 is different from the thin-film solar cell 11 according to the first embodiment in that the conductive oxide light scatterers 4c are also formed as conductive light scatterers on the second power generation layer 8 of the thin-film solar cell 11 of the tandem type.

In the thin-film solar cell 20 according to the second embodiment configured as explained above, the conductive oxide light scatterers 4b as fine granular conductive light scatterers are formed on the first transparent conductive films 2. The conductive oxide light scatterers 4b and the first transparent conductive films 2 are formed as a texture-like transparent conductive film 7 having small surface roughness as a whole. Light made incident from the transparent insulative substrate 1 side is made incident on the first power generation layer 5 after being scattered on the interface between the first transparent conductive films 2 having the conductive oxide light scatterers 4b and the first power generation layer 5. Therefore, the light is made incident generally obliquely on the first power generation layer 5. Because the light is made incident obliquely on the first power generation layer 5, a substantial optical path of the light is extended and absorption of the light increases. Therefore, a photoelectric conversion characteristic of the thin-film solar cell is improved and output current increases. Consequently, a thin-film solar cell that has a satisfactory light diffusion effect and is excellent in conversion efficiency is realized.

On the conductive oxide light scatterers 4b, irregularities are equally formed such that there is no steep slope on irregularities of the transparent conductive film. Consequently, structural defects induced by an irregular structure for light scattering in the first power generation layer 5 formed on the first transparent conductive films 2 are reduced. Short-circuit and leak due to the structural defects induced in the first power generation layer 5 are reduced.

In the thin-film solar cell 20 according to the second embodiment, the conductive oxide light scatterers 4c as fine granular conductive light scatterers are formed between the second power generation layer 8 and the rear-side electrode layer 6. The rear-side electrode layer 6 having small surface roughness as a whole is formed. Light reflected on the rear-side electrode layer 6 is made incident on the second power generation layer 8 after being scattered on an interface between the rear-side electrode layer 6 having the conductive oxide light scatterers 4c and the second power generation layer 8. Therefore, the light is made incident generally obliquely on the second power generation layer 8. Because the light is made incident obliquely on the second power generation layer 8, a substantial optical path of the light is extended and absorption of the light increases. Therefore, a photoelectric conversion characteristic of the thin-film solar cell is improved and output current increases. Consequently, a thin-film solar cell that has a satisfactory light diffusion effect and is excellent in conversion efficiency is realized.

Therefore, in the thin-film solar cell 20 according to the second embodiment, a thin-film solar cell is realized that has a satisfactory light diffusion effect, in which short-circuit and leak of the first power generation layer 5 and the second power generation layer 8 are reduced, and that is excellent in reliability and yield. Further, a thin-film solar cell having high conversion efficiency is realized by using the sunlight having wavelength not contributing to power generation in the past.

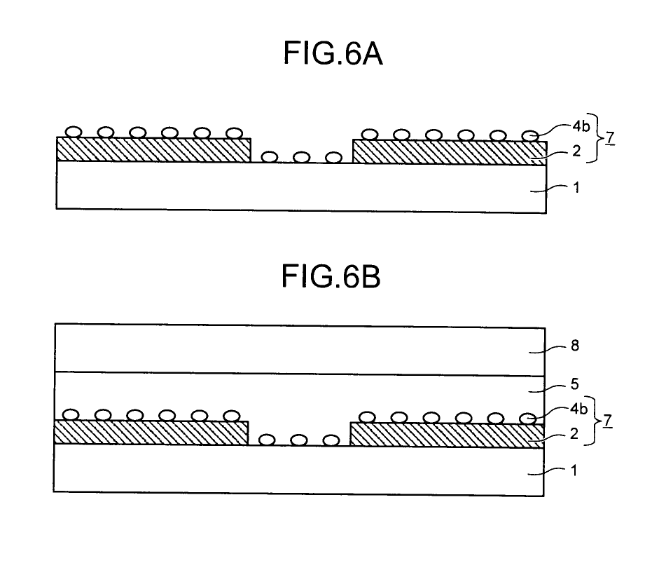

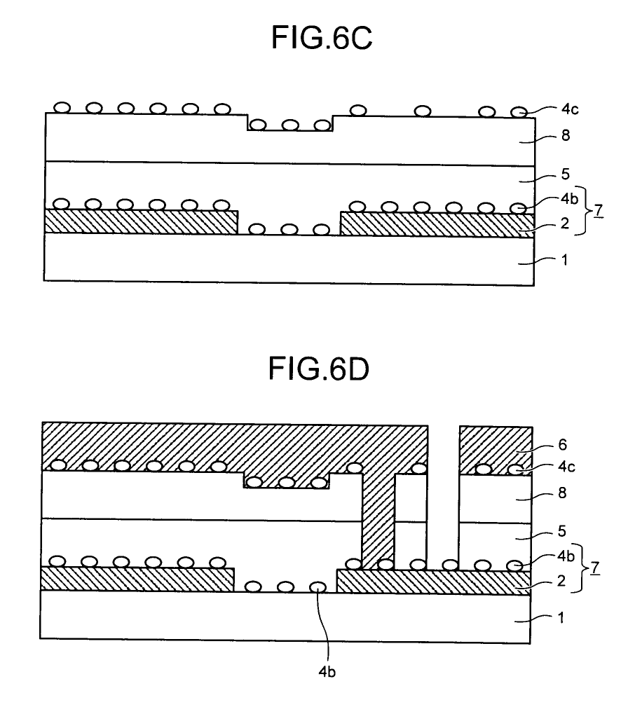

A method of manufacturing the thin-film solar cell 20 of the tandem type configured as explained above is explained with reference to FIGS. 6-1 to 6-4. FIGS. 6-1 to 6-4 are sectional views for explaining a manufacturing process for the thin-film solar cell 20 according to the second embodiment. Explanation of a manufacturing method same as that in the first embodiment is omitted. First, the conductive oxide light scatterers 4b including zinc oxide crystal grains are formed on the glass substrate 1 and the first transparent conductive films 2 as shown in FIG. 6-1 by carrying out the process explained with reference to FIGS. 2-1 to 2-5 in the first embodiment.

Subsequently, the first power generation layer 5 is formed on the first transparent conductive films 2 and the conductive oxide light scatterers 4b (the zinc oxide crystal grains) by the PCVD method. In this embodiment, as the first power generation layer 5, a P-type a-SiC film, a buffer layer, an i-type a-Si film, and an N-type a-Si film are formed in order from the first transparent conductive films 2 side.

Subsequently, the second power generation layer 8 is formed on the first power generation layer 5 by the PCVD method. In this embodiment, as the second power generation layer 8, a P-type microcrystal silicon film (μc-Si film), an i-type microcrystal silicon film (μc-Si film), and an N-type microcrystal silicon film (μc-Si film) are formed in order from the first power generation layer 5 side (FIG. 6-2).

Subsequently, patterning is applied to the second power generation layer 8 by the laser scribe in the same manner as the patterning for the first transparent conductive films 2. The conductive oxide light scatterers 4c including zinc oxide crystal grains are formed on the second power generation layer 8 by a method same as the method of manufacturing the conductive oxide light scatterers 4b (FIG. 6-3).

Subsequently, patterning is applied to the first power generation layer 5 and the second power generation layer 8 by the laser scribe in the same manner as the patterning for the first transparent conductive films 2. The rear-side electrode layer 6 serving as the second electrode layer is formed on the second power generation layer 8 by the sputtering method to fill grooves of the patterning. In this embodiment, a ZnO film having thickness of 200 nanometers, an Ag film having thickness of 100 nanometers, and an aluminum (Al) film having thickness of 100 nanometers are formed from the second power generation layer 8 side.

After the formation of the rear-side electrode layer 6, a metal layer is locally blown off by a laser together with semiconductor layers (the first power generation layer 5 and the second power generation layer 8), whereby the semiconductor layers and the metal layer are separated to correspond to a plurality of unit elements (power generation areas) (FIG. 6-4). Because it is difficult to cause the rear-side electrode layer 6 having the high reflectance to directly absorb the laser, the semiconductor layers (the first power generation layer 5 and the second power generation layer 8) are caused to absorb laser beam energy and the metal layer is locally blown off together with the semiconductor layers (the first power generation layer 5 and the second power generation layer 8), whereby the semiconductor layers and the metal layer are separated to correspond to the unit elements (the power generation areas). According to the process explained above, the thin-film solar cell 20 shown in FIG. 5 is formed.

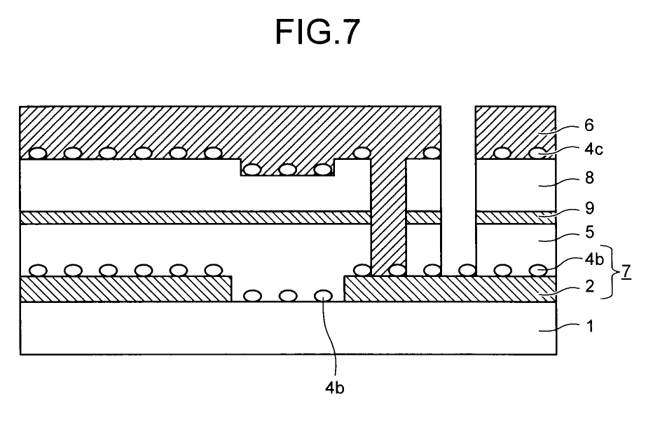

As shown in FIG. 7, a transparent film of ZnO, ITO, SnO₂, SiO, or the like having conductivity can be formed as an intermediate layer 9 between the first power generation layer 5 and the second power generation layer 8 in FIG. 5.

In the method of manufacturing a thin-film solar cell according to the second embodiment explained above, the conductive oxide light scatterers 4b as fine granular conductive light scatterers are formed on the first transparent conductive films 2 and the texture-like transparent conductive film 7 having small surface roughness as a whole is formed. The conductive oxide light scatterers 4c as fine granular conductive light scatterers are formed between the second power generation layer 8 and the rear-side electrode layer 6. The rear-side electrode layer 6 having small surface roughness as a whole is formed. This makes it possible to manufacture a thin-film solar cell that has a satisfactory light diffusion effect and is excellent in conversion efficiency.

By applying etching to the transparent conductive film with two kinds of acid solutions having different characteristics, it is possible to form the conductive oxide light scatterers 4b to equalize irregularities such that there is no steep slope on irregularities of the transparent conductive film as a whole. This makes it possible to reduce structural defects induced by the irregular structure for light scattering in the first power generation layer 5 and the second power generation layer 8 formed on the first transparent conductive films 2 and manufacture a thin-film solar cell in which short-circuit and leak due to the structure defects induced in the first power generation layer 5 and the second power generation layer 8 are reduced and that is excellent in reliability and yield. Further, it is possible to manufacture a thin-film solar cell having high conversion efficiency by using the sunlight having wavelength not contributing to power generation in the past.

The present invention is explained below based on specific examples. The thin-film solar cell 20 manufactured by the method of manufacturing a thin-film solar cell according to the second embodiment explained above is a thin-film solar cell of an example 2. As a conventional example, a thin-film solar cell of the tandem type in which the conductive oxide light scatterers 4b and the conductive oxide light scatterers 4c are not formed is manufactured in the method of manufacturing a thin-film solar cell according to the second embodiment. This thin-film solar cell is a thin-film solar cell of the conventional example 3.

Light having an AM (air mass) of −1.5 and 100 mW/cm² was made incident on the thin-film solar cells from a substrate side using a solar simulator, short-circuit currents (mA/cm²) were measured at 25° C., and characteristics of the thin-film solar cells were evaluated. A result of the evaluation is shown in Table 2.

TABLE 2

| | Short-circuit currents |
|---|---|
| | [mA/cm²] |
| Example 2 | 13.2 |
| Conventional example 3 | 11.5 |

It is recognized from Table 2 that, whereas short-circuit current of the thin-film solar cell of the conventional example 3 is 11.5 mA/cm², short-circuit current of the thin-film solar cell of the example 2 is 13.2 mA/cm² and the short-circuit current (mA/cm²) is improved 10% or more in the thin-film solar cell of the example 2 compared with the thin-film solar cell of the conventional example 3. This is because the conductive oxide light scatterers 4b are formed such that there is no steep slope on irregularities of the transparent conductive film as a whole and the irregularities are equalized. Further, this is because the conductive oxide light scatterers 4b are formed such that there is no steep slope on irregularities of the rear-side electrode layer 6 as a whole and the irregularities are equalized.

Specifically, the light made incident from the transparent insulative substrate side is made incident on the first power generation layer 5 after being scattered on the interface between the first transparent conductive films 2 having the conductive oxide light scatterers 4b and the first power generation layer 5. Therefore, the light is made incident generally obliquely on the first power generation layer 5. Because the light is made incident obliquely on the first power generation layer 5, a substantial optical path of the light is extended and absorption of the light increases. Therefore, a photoelectric conversion characteristic of the thin-film solar cell is improved and output current increases. Structural defects induced in the first power generation layer 5 and the second power generation layer 8 by the irregular structure for light scattering are reduced and short-circuit and the like and leak are reduced.

Light reflected on the rear-side electrode layer 6 is made incident on the second power generation layer 8 after being scattered on the interface between the rear-side electrode layer 6 having the conductive oxide light scatterers 4c and the second power generation layer 8. Therefore, the light is made incident generally obliquely on the second power generation layer 8. Because the light is made incident obliquely on the second power generation layer 8, a substantial optical path of the light is extended and absorption of the light increases. Therefore, a photoelectric conversion characteristic of the thin-film solar cell is improved and output current increases.

With the thin-film solar cell and the method of manufacturing the same according to the second embodiment explained above, a thin-film solar cell is realized that has a satisfactory light trapping effect by the texture structure for light scattering, in which deterioration in reliability and a photoelectric conversion characteristic due to the texture structure for light scattering is prevented, and that is excellent in the reliability and the photoelectric conversion characteristic and can be used for a long period.

In the embodiment, the zinc oxide crystal grains 4a are changed to the conductive oxide light scatterers 4b and 4c by the second etching. However, the zinc oxide crystal grains 4a formed by the first etching can be changed to light scatterers. When the second etching is performed, the zinc oxide crystal grains 4a do not always have to be changed to diffused gains in the first etching. For example, the zinc oxide crystal grains 4a can be processed into a rough surface having irregularities in the first etching and changed to diffused grains in the second etching.

### Third Embodiment

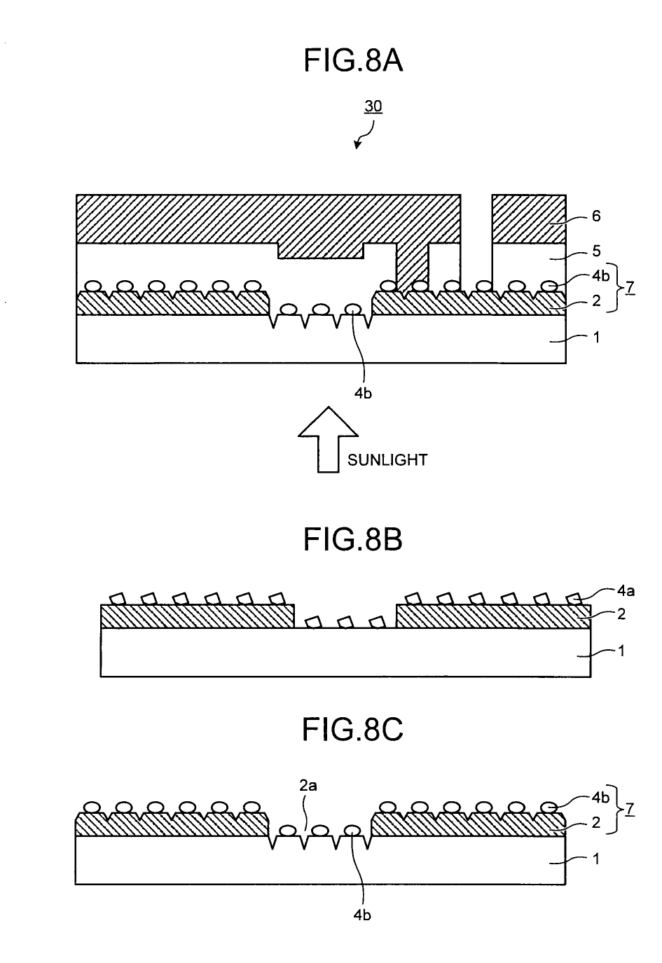

FIG. 8-1 is a sectional view of a schematic configuration of a thin-film solar cell 30 according to a third embodiment of the present invention. The thin-film solar cell 30 according to the third embodiment is a modification of the thin-film solar cell 11 according to the first embodiment. Like the thin-film solar cell 10, the thin-film solar cell 30 includes the transparent insulative substrate 1, the first transparent conductive films (the transparent electrode layers) 2, the conductive oxide light scatterers 4b, the first power generation layer 5, and the rear-side electrode layer 6. In FIG. 8-1, members same as those of the thin-film solar cell 10 according to the first embodiment are denoted by reference numerals and signs same as those in FIG. 1 and explanation of the members is omitted.

The thin-film solar cell 30 is different from the thin-film solar cell 10 according to the first embodiment in that irregular shapes having a large difference of elevation (surface roughness Rmax) are formed on the surfaces of the first transparent conductive films (the transparent electrode layers) 2 and an area between the separated first transparent conductive films 2 on the surface of the transparent insulative substrate 1.

In the thin-film solar cell 30 according to the third embodiment configured as explained above, as in the thin-film solar cell 10, the conductive oxide light scatterers 4b as fine granular conductive light scatterers are formed on the first transparent conductive films 2. The conductive oxide light scatterers 4b and the first transparent conductive films 2 are formed as the texture-like transparent conductive film 7 having small surface roughness as a whole. Light made incident from the transparent insulative substrate 1 side is made incident on the first power generation layer 5 after being scattered on the interface between the first transparent conductive films 2 having the conductive oxide light scatterers 4b and the first power generation layer 5. Therefore, the light is made incident generally obliquely on the first power generation layer 5. Because the light is made incident obliquely on the first power generation layer 5, a substantial optical path of the light is extended and absorption of the light increases. Therefore, a photoelectric conversion characteristic of the thin-film solar cell is improved and output current increases. Consequently, like the thin-film solar cell 10, a thin-film solar cell that has a satisfactory light diffusion effect and is excellent in conversion efficiency is realized.

On the conductive oxide light scatterers 4b, irregularities are equally formed such that there is no steep slope on irregularities of the transparent conductive film. Consequently, structural defects induced by an irregular structure for light scattering in the first power generation layer 5 formed on the first transparent conductive films 2 are reduced. Short-circuit and leak due to the structural defects induced in the first power generation layer 5 are reduced.

In the thin-film solar cell 20 according to the third embodiment, the irregular shapes having a large difference of elevation (surface roughness Rmax) are formed on the surfaces of the first transparent conductive films (the transparent electrode layers) 2 and the area between the separated first transparent conductive films 2 on the surface of the transparent insulative substrate 1. Light made incident from the transparent insulative substrate 1 side is made incident on the first power generation layer 5 after being scattered on the interface between the first transparent conductive films 2 having the conductive oxide light scatterers 4b and the first power generation layer 5 and, in addition, being also scattered on an interface between the irregular shapes formed on the surfaces of the first transparent conductive films (the transparent electrode layers) 2 and the area between the separated first transparent conductive films 2 on the surface of the transparent insulative substrate 1. Therefore, the light is made incident generally obliquely on the first power generation layer 5. Because the light is made incident obliquely on the second power generation layer 8, a substantial optical path of the light is extended and absorption of the light increases. Therefore, a photoelectric conversion characteristic of the thin-film solar cell is improved and output current increases. Consequently, a thin-film solar cell that has a satisfactory light diffusion effect and is excellent in conversion efficiency is realized.

Therefore, in the thin-film solar cell 30 according to the third embodiment, a thin-film solar cell is realized that has a satisfactory light diffusion effect, in which short-circuit and leak of the first power generation layer 5 and the second power generation layer 8 are reduced, and that is excellent in reliability and yield. Further, a thin-film solar cell having high conversion efficiency is realized by using the sunlight having wavelength not contributing to power generation in the past.

A method of manufacturing the thin-film solar cell 30 of the tandem type configured as explained above is explained with reference to FIGS. 8-2 and 8-3. FIGS. 8-2 and 8-3 are sectional views for explaining a manufacturing process for the thin-film solar cell 30 according to the third embodiment. Explanation of a manufacturing method same as that in the first embodiment is omitted. First, the zinc oxide crystal grains 4a including zinc oxide crystal grains are formed on the glass substrate 1 and the first transparent conductive films 2 by carrying out the process explained with reference to FIGS. 2-1 to 2-4 in the first embodiment (FIG. 8-2).

Subsequently, second etching is performed to etch the zinc oxide crystal grains 4a and form the conductive oxide light scatterers 4b including zinc oxide crystal grains on the glass substrate 1 and the first transparent conductive films 2 (FIG. 8-3). In the second etching, a parallel plate type reactive ion etching (RIE) method is used. The etching is performed under conditions that an etching gas is tetrafluloromethane (CF₄), an etching gas flow rate is 50 sccm, etching gas pressure is 5.0 Pa, applied power (RF) is 200 W, and processing time is 10 minutes. As the etching gas, a mixed gas of a simple substance gas of gas containing fluorine-based trifloromethane (CHF₃), tetrafluoromethane (CF₄), or sulfur hexafluororode (SF₆) or argon (Ar) and gas such as oxygen (O₂) or helium (He), a chlorine gas, or the like can be used. By using this dry etching method, it is possible to form zinc oxide crystal grains that are the substantially spherical conductive oxide light scatterers 4b having a smooth surface as in the case of the first embodiment (FIG. 8-3). As explained above, when the dry etching method is used in the second etching, it is also possible to form the conductive oxide light scatterers 4b in the same manner as etching the zinc oxide crystal grains 4a using acid etching liquid. By adjusting an etching condition, it is possible to set the resistance in a surface direction of the conductive oxide light scatterers 4b sufficiently high and suppress occurrence of short-circuit among elements and leak current.

In this RIE, the surfaces of the first transparent conductive films (the transparent electrode layers) 2 and the surface of the transparent insulative substrate 1 in the first open groove (the scribe line) 2a, which is the area between the separated first transparent conductive films 2, are also simultaneously etched and irregular shapes are formed. Consequently, irregular structures having a larger difference of elevation are formed on the surfaces of the first transparent conductive films (the transparent electrode layers) 2 and the surface of the transparent insulative substrate 1 in the first open groove (the scribe line) 2a. Thereafter, the thin-film solar cell 30 shown in FIG. 8-1 can be manufactured by carrying out the process explaining with reference to FIGS. 2-6 and 2-7.

With the thin-film solar cell and the method of manufacturing the same according to the third embodiment explained above, a thin-film solar cell is realized that has a satisfactory light trapping effect by the texture structure for light scattering, in which deterioration in reliability and a photoelectric conversion characteristic due to the texture structure for light scattering is prevented, and that is excellent in the reliability and the photoelectric conversion characteristic and can be used for a long period.

In the embodiments explained above, the amorphous silicon thin-film solar cell, the thin-film polycrystal silicon solar cell, and the tandem type of the solar cells are explained. However, the present invention can be extensively applied to thin-film solar cells in general such as a compound semiconductor thin-film solar cell.

### INDUSTRIAL APPLICABILITY

As explained above, the method of manufacturing a thin-film solar cell according to the present invention is useful for applications that require reliability and a photoelectric conversion characteristic.

1. A method of manufacturing a thin-film solar cell, comprising:
a first transparent conductive film forming step for forming a plurality of first transparent conductive films separated from one another in a substrate surface on a transparent insulative substrate;
a second transparent conductive film forming step for forming a second transparent conductive film on the first transparent conductive films;
an etching step for etching the second transparent conductive film in a granular shape and forming first granular members dispersed on the first transparent conductive films;
a power generation layer forming step for forming a first power generation layer on the first transparent conductive films and on the dispersed first granular members; and
a rear-side electrode layer forming step for forming a rear-side electrode layer on the power generation layer.

2. The method of manufacturing a thin-film solar cell according to claim 1, wherein, in the etching step, etching speed for the second transparent conductive film is higher than etching speed for the first transparent conductive films and the second transparent conductive film is processed into the first granular members dispersed on the first transparent conductive films by etching liquid.

3. The method of manufacturing a thin-film solar cell according to claim 2, wherein the etching step includes further etching, after the second transparent conductive film is processed into the first granular members dispersed on the first transparent conductive film by the etching liquid, the dispersed first granular members with another etching liquid having an etching speed ratio of the second transparent conductive film to etching speed of the first transparent conductive film larger than that of the etching liquid and forming a finer first fine granular members.

4. The method of manufacturing a thin-film solar cell according to claim 1, wherein
the second transparent conductive film is a film containing zinc oxide as a main component, and
in the etching step, after the second transparent conductive film is etched by first solution containing oxalic acid, the second transparent conductive film is etched by second solution containing any one of hydrochloric acid, sulfuric acid, nitric acid, fluoric acid, acetic acid, and formic acid.

5. The method of manufacturing a thin-film solar cell according to claim 1, wherein
the method includes, between the power generation layer forming step and the rear-side electrode layer forming step:
a third transparent conductive film forming step for forming a third transparent conductive film that is equivalent to the second transparent conductive film on a surface of a second power generation layer formed on the first power generation layer; and
an etching step for etching the third transparent conductive film in a granular shape and forming second granular members dispersed on the second power generation layer, and
the rear-side electrode forming step includes forming the rear-side electrode layer on the dispersed second granular members and on the second power generation layer.

6. The method of manufacturing a thin-film solar cell according to claim 1, wherein the etching step includes etching the second transparent conductive film in a granular shape among the first transparent conductive films on the transparent insulative substrate and forming third granular members that are equivalent to the first granular members and dispersed between the first transparent conductive films adjacent to each other on the transparent insulative substrate.

7. The method of manufacturing a thin-film solar cell according to claim 6, wherein the etching step includes further etching, after the second transparent conductive film is processed into the third granular members by the etching liquid, the dispersed third granular members with another etching liquid having an etching speed ratio of the second transparent conductive film to etching speed of the first transparent conductive film larger than that of the etching liquid and forming a finer second fine granular members.

8. The method of manufacturing a thin-film solar cell according to claim 7, wherein the dispersed third granular members are etched such that separation resistance between the first transparent conductive films separated from each other on the transparent insulative substrate is equal to or larger than 1 megaohm.

9. The method of manufacturing a thin-film solar cell according to claim 1, wherein
the second transparent conductive film is a film containing zinc oxide as a main component, and
the etching step includes etching, after the second transparent conductive film is etched by first solution containing oxalic acid, the second transparent conductive film with parallel plate type reactive ion etching using a mixed gas, which is obtained by mixing any one simple substance gas among trifloromethane, tetrafluoromethane, sulfur hexafluororode, and argon and oxygen or helium to thereby form third fine granular members and forming irregular shapes on a surface of the first transparent conductive film and a surface between the adjacent first transparent conductive films on the transparent insulative substrate.

10. A thin-film solar cell comprising:
a transparent insulative substrate;
a first transparent conductive film formed on the transparent insulative substrate;
dispersed first granular members formed of a transparent conductive material different from the first transparent conductive film formed on a surface of the first transparent conductive film;
a power generation layer formed on the first transparent conductive film and on the dispersed first granular members; and
a rear-side electrode layer formed on the power generation layer.

11. The thin-film solar cell according to claim 10, wherein the dispersed first granular members are formed of a material containing zinc oxide as a main component.

12. The thin-film solar cell according to claim 10, wherein the thin-film solar cell includes dispersed second granular members formed of a transparent conductive material between the power generation layer and the rear-side electrode layer.

13. The thin-film solar cell according to claim 10, wherein
the thin-film solar cell includes a plurality of the first transparent conductive films separated from one another in a substrate surface on the transparent insulative substrate, and
the thin-film solar cell includes, between the first transparent conductive films separated from each other on the transparent insulative substrate, dispersed third granular members that are equivalent to the first granular members and formed of a transparent conductive material different from the first transparent conductive films.

14. The thin-film solar cell according to claim 13, wherein separation resistance between the first transparent conductive films separated from each other is equal to or larger than 1 megaohm.

15. The thin-film solar cell according to claim 13, wherein the thin-film solar cell has irregular shapes on surfaces of the first transparent conductive films and a surface between the adjacent first transparent conductive films on the transparent insulative substrate.
